(19) United States
(12) Patent Application Publication
(10) Pub. No.: US 2025/0164411 A1
(43) Pub. Date: May 22, 2025

(54) Methods And Systems For Spectral Measurements Based On Perturbed Spectra

(71) Applicant: KLA Corporation, Milpitas, CA (US)

(72) Inventors: William McGahan, Spicewood, TX (US); Shankar Krishnan, Cupertino, CA (US)

(21) Appl. No.: 18/911,630

(22) Filed: Oct. 10, 2024

Related U.S. Application Data
(60) Provisional application No. 63/544,841, filed on Oct. 19, 2023.

(51) Int. Cl. G01N 21/95; G01N 23/20025

(52) U.S. Cl. CPC G01N 21/9501; G01N 23/20025; G01N 2223/052; G01N 2223/6116; G01N 2223/646

(57) ABSTRACT

Methods and systems for measuring structural parameters characterizing a measurement target based on changes in measurement signal values due to one or more perturbations of an effective illumination angle of incidence on the measurement target are presented herein. In some examples, a measurement model estimates values of the structural parameters based on the changes in measurement signal values. In some examples, at least one derivative of detected measurement signals with respect to effective illumination angle is determined, and values of the structural parameters are estimated based on the at least one derivative. In some examples, values of one or more tunable measurement model parameters are estimated based on at least one derivative. In some examples, the fitting performance of a measurement model is quantified based on measurements performed at both unperturbed and perturbed orientations of a structure under measurement with respect to the illumination beam.

### CROSS REFERENCE TO RELATED APPLICATION

The present application for patent claims priority under 35 U.S.C. § 119 from U.S. provisional patent application Ser. No. 63/544,841, entitled “Method for Measurement of Derivative Spectra Using a Spectroscopic Ellipsometer,” filed Oct. 19, 2023, the subject matter of which is incorporated herein by reference in its entirety.

### TECHNICAL FIELD

The described embodiments relate to metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical and x-ray based metrology techniques offer the potential for high throughput without the risk of sample destruction. A number of techniques including scatterometry, ellipsometry, and reflectometry implementations and associated analysis algorithms are commonly used to characterize critical dimensions, film thicknesses, composition, overlay, and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. In some examples, semiconductor devices are increasingly valued based on their energy efficiency, rather than speed alone. For example, energy efficient consumer products are more valuable because they operate at lower temperatures and for longer periods of time on a fixed battery power supply. In another example, energy efficient data servers are in demand to reduce their operating costs. As a result, there is a strong interest to reduce the energy consumption of semiconductor devices. Solutions include the use of high-K material layers and complex geometric structures, both of which contribute to characterization difficulty.

Modern semiconductor processes are employed to produce complex structures. A complex measurement model with multiple parameters is required to represent these structures and account for process and dimensional variations. Complex, multiple parameter models include modeling errors induced by parameter correlations and low measurement sensitivity to some parameters. In addition, regression of complex, multiple parameter models having a relatively large number of floating parameter values may not be computationally tractable. In some examples, a number of parameters are typically fixed in a model-based measurement to reduce the impact of these error sources and reduce computational effort. Although fixing the values of a number of parameters may improve calculation speed and reduce the impact of parameter correlations, it also leads to errors in the estimates of parameter values.

Various measurement techniques have been proposed to increase measurement sensitivity and break parameter correlations that limit measurement system performance in demanding applications.

In some examples, measurements are performed while the local environment around a metrology target under measurement is treated with a flow of purge gas that includes a controlled amount of fill material. A portion of the fill material condenses onto the structures under measurement and fills openings in the structural features, openings between structural features, etc. The presence of the fill material changes the optical properties of the structure under measurement compared to a measurement scenario where the purge gas is devoid of any fill material. Model based measurements are performed with an enriched data set including measurement signals collected from the metrology target having geometric features filled with fill material. This reduces parameter correlation among floating measurement parameters and improves measurement accuracy. In this manner, model-based measurement results can be obtained with reduced computational effort. Further details are described in U.S. Pat. No. 10,145,674 assigned to KLA-Tencor Corporation, Milpitas, California, the contents of which are incorporated herein by reference in their entirety. Unfortunately, applying a fill material to a wafer introduces problems with contamination of the wafer itself, limited contrast induced by the fill material, lack of flexibility in the selection of the fill material, increased system complexity, and increased risk due to contact with the wafer surface.

In some other examples, various forms of modulation spectroscopy, e.g., photo-modulated reflectivity and electroreflectance spectroscopy, are employed. In these examples, periodic changes are induced in the electric field of the sample under test. The modulation of the electric field effectively causes a modulation of the dielectric function of the sample materials at the same frequency.

Currently, the solution of complex, multiple parameter measurement models often requires an unsatisfactory compromise. Current model reduction techniques are sometimes unable to arrive at a measurement model that is both computationally tractable and sufficiently accurate. Moreover, complex, multiple parameter models make it difficult, or impossible, to optimize system parameter selections (e.g., wavelengths, angles of incidence, etc.) for each parameter of interest.

Future metrology applications present challenges due to increasingly small resolution requirements, multi-parameter correlation, increasingly complex geometric structures, and increasing use of opaque materials. Accordingly, it would be advantageous to develop high throughput systems and methods for characterizing complex semiconductor structures in a robust, reliable, and stable manner. Thus, methods and systems for improved measurements of semiconductor structures are desired.

### SUMMARY

Methods and systems for measuring structural parameters characterizing a measurement target based on changes in measurement signal values resulting from one or more perturbations of an effective incidence angle of an illumination beam with respect to the measurement target are presented herein.

Measurements of the sample are performed in an unperturbed orientation of the sample with respect to the illumination beam and one or more perturbed orientations of the sample with respect to the illumination beam. The perturbation of the orientation of the sample with respect to the illumination beam induces changes in the measurement signal values. The changes in the measurement signal values are provided as input to a measurement model, either directly or indirectly. The measurement model estimates values of one or more parameters of interest characterizing one or more structural elements of the measurement target based on the changes in measurement signal values. In this manner, the measurement model operates on derivative information, i.e., changes in measurement signals as a function of changes in orientation of the sample with respect to the illumination beam, to estimate values of one or more parameters of interest. In some examples, measurements based on these derivative quantities enable increased sensitivity to film and CD parameters with reduced correlations among the parameters characterizing different materials comprising the structure under measurement.

In some examples, an angle of incidence in the illumination plane and an azimuth angle define the effective angle of incidence of an illumination beam with respect to one or more structures under measurement. In some of these examples, a wafer stage positions a wafer with respect to an illumination beam at both unperturbed and perturbed angles of incidence, azimuth angle, or both.

In one aspect, spectral measurements of a structure of interest at both an unperturbed effective illumination angle and a perturbed effective illumination angle are collected and employed to estimate a value of at least one parameter of interest characterizing the structure of interest.

In some embodiments, a perturbation based measurement engine estimates values of one or more parameters of interest characterizing a structure under measurement based on changes in measurement signal values induced by changes in the effective illumination angle.

In some embodiments, a derivative estimation engine determines at least one derivative of the detected measurement signals with respect to the effective illumination angle. A derivative estimation engine receives measurement signals associated with measurements performed in an unperturbed orientation of one or more structures under measurement with respect to the illumination beam and measurement signals associated with measurements performed in one or more perturbed orientations of the one or more structures under measurement with respect to the illumination beam. In addition, the derivative estimation engine receives a difference between the unperturbed orientation and the one or more perturbed orientations. In some embodiments, the derivative estimation engine employs a finite difference algorithm to approximate derivatives based on the difference between perturbed and unperturbed measurement signals and the corresponding differences in orientation.

In some embodiments, a derivative based measurement engine estimates values of one or more parameters of interest characterizing a structure under measurement based on at least one derivative of the detected measurement signals with respect to the effective illumination angle. In these embodiments, derivative signals, e.g., derivative spectra, are additional data quantities employed to fit a structural measurement model to the measured signals. In general, the additional derivative signals help to break correlations between model parameters, improve measurement precision and accuracy, reduce computational effort required to converge on a solution, etc.

In some embodiments a derivative based measurement model tuning engine estimates values of one or more measurement model parameters based on at least one derivative of the detected measurement signals with respect to the effective illumination angle. In these embodiments, derivative signals, e.g., derivative spectra, are additional data quantities employed to fit a structural measurement model to the measured signals. The model parameters subject to tuning are typically maintained as fixed valued variables when performing model based measurement of one or more parameters of interest characterizing one or more structures under measurement.

In some embodiments, a perturbation based measurement model evaluation engine quantifies the fitting performance of a measurement model for measurements performed at both unperturbed and perturbed orientations of a structure under measurement with respect to the illumination beam. The measured fitting performance may be used to determine whether the measurement model requires structural changes, additional parameter tuning, or both, before implementation in a production scenario.

The methods and systems described herein enable improved measurements of structural elements common in semiconductor manufacturing, e.g., material composition, alloy fraction measurements of compound semiconductors, material band gap, characterization of semiconductor surfaces and interfaces, film layer properties, critical dimensions, etc. Measurement applications include measurements of structural elements comprising complex semiconductor structures such as 3D VNAND structures and Gate-All-Around (GAA) structures, including front-end-of-line (FEOL) layers from oxide definition layers to high-k metal gate (HKMG) stacks. Measurement applications include measurements of structural elements comprised of semiconducting materials, insulating dielectric materials, and conducting materials, including organic materials, inorganic materials, or a combination thereof.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a spectroscopic ellipsometry system configured to measure structural features of a semiconductor measurement target based on changes in measurement signal values resulting from a perturbation of an effective incidence angle of the illumination beam with respect to the measurement target.

FIG. 2 is a diagram illustrative of some elements of the wafer stage depicted in FIG. 1.

FIG. 3 is a diagram illustrative of a perturbation based measurement engine 160 in one embodiment.

FIG. 4 is a diagram illustrative of a derivative estimation engine 150 in one embodiment.

FIG. 5 is a diagram illustrative of a derivative based measurement engine 170 in one embodiment.

FIG. 6 is a diagram illustrative of a derivative based measurement model tuning engine 185 in one embodiment.

FIG. 7 is a diagram illustrative of a perturbation based measurement model evaluation engine 200 in one embodiment

FIG. 8 is a flowchart illustrative of a method 300 for measuring structural features of a semiconductor measurement target based on changes in measurement signal values resulting from a perturbation of an effective incidence angle of the illumination beam with respect to the measurement target, as described herein.

### DETAILED DESCRIPTION

Reference will now be made in detail to background examples and some embodiments of the invention, examples of which are illustrated in the accompanying drawings.

Methods and systems for measuring structural parameters characterizing a measurement target based on changes in measurement signal values resulting from one or more perturbations of an effective incidence angle of an illumination beam with respect to the measurement target are presented herein. Measurements of the sample are performed in an unperturbed orientation of the sample with respect to the illumination beam and one or more perturbed orientations of the sample with respect to the illumination beam. In preferred embodiments, the perturbed orientation of the sample is realized by introducing a small rotation of the sample from the unperturbed orientation using a wafer stage configured to orient the sample with respect to the illumination beam with relatively high resolution.

A perturbation of the orientation of a sample with respect to the illumination beam induces changes in the measurement signal values. The changes in the measurement signal values are provided as input to a measurement model, either directly or indirectly. In this manner, the measurement is based on the derivatives of measurement signals with respect to angular orientation of the sample with respect to the illumination beam. In some examples, measurements based on these derivative quantities enable increased sensitivity to film and CD parameters with reduced correlations among the parameters characterizing different materials comprising the structure under measurement.

The measurement model estimates values of one or more parameters of interest characterizing one or more structural elements of the measurement target based on the changes in measurement signal values. In this manner, the measurement model operates on derivative information, i.e., changes in measurement signals as a function of changes in orientation of the sample with respect to the illumination beam, to estimate values of one or more parameters of interest.

The methods and systems described herein are applicable to a wide range of contactless and non-destructive measurement systems, e.g., optical, electron-based, and x-ray based measurement systems, operating in any number of signal modalities, e.g., reflectometry, ellipsometry, scatterometry, pupil imagery, field imagery, hyperspectral imagery, etc. Model based measurements performed based on derivative information as described herein breaks correlations and provides sensitivity to structural parameters that would not otherwise be accessible by contactless and non-destructive measurement systems.

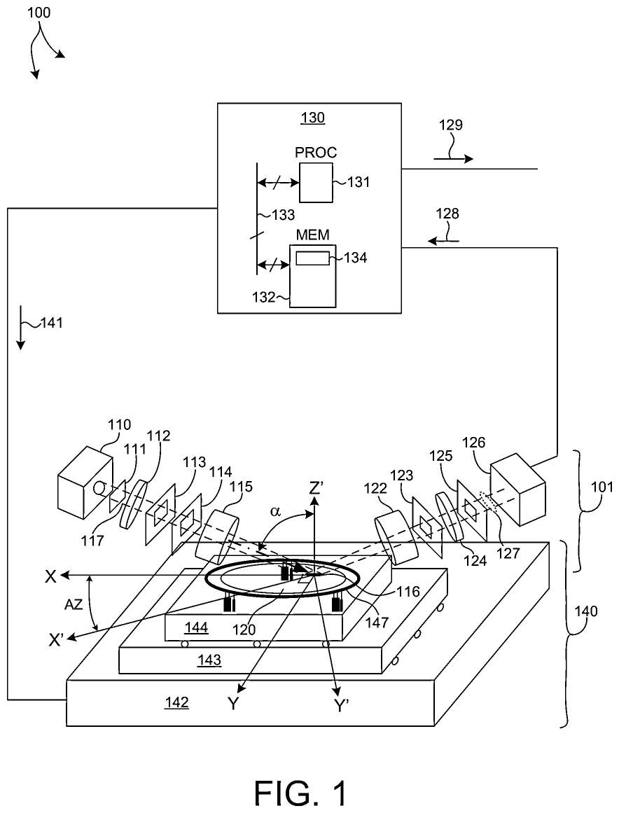

FIG. 1 depicts an exemplary, metrology system 100 for performing measurements of structural features of semiconductor devices. As depicted in FIG. 1, metrology system 100 is configured as a broadband spectroscopic ellipsometer. However, in general, metrology system 100 may be configured as a spectroscopic reflectometer, scatterometer, single wavelength ellipsometer, beam profile reflectometer, or any combination thereof.

Metrology system 100 includes an illumination source 110 that generates a beam of illumination light 117 incident on a wafer 120. In some embodiments, illumination source 110 is a broadband illumination source that emits illumination light in the ultraviolet, visible, and infrared spectra. In one embodiment, illumination source 110 is a laser sustained plasma (LSP) light source (a.k.a., laser driven plasma source). The pump laser of the LSP light source may be continuous wave or pulsed. A laser-driven plasma source can produce significantly more photons than a Xenon lamp across a wavelength range from 150 nanometers to 2000 nanometers. Illumination source 110 can be a single light source or a combination of a plurality of broadband or discrete wavelength light sources. The light generated by illumination source 110 includes a continuous spectrum or parts of a continuous spectrum, from ultraviolet to infrared (e.g., vacuum ultraviolet to mid infrared). In general, illumination light source 110 may include a super continuum laser source, an infrared helium-neon laser source, an arc lamp, a globar source, or any other suitable light source.

In some embodiments, the amount of illumination light is broadband illumination light that includes a range of wavelengths spanning at least 500 nanometers. In one example, the broadband illumination light includes wavelengths below 250 nanometers and wavelengths above 750 nanometers. In general, the broadband SE illumination light includes wavelengths between 120 nanometers and 4,200 nanometers. In some embodiments, broadband illumination light including wavelengths beyond 4,200 nanometers may be employed. In some embodiments, illumination source 110 includes a deuterium source emitting light with wavelengths across a range from 150 nanometers to 400 nanometers, a LSP source emitting light with wavelengths across a range from 180 nanometers to 2,500 nanometers, a supercontinuum source emitting light with wavelengths across a range from 400 nanometers to 4,200 nanometers, and a globar source emitting light with wavelengths across a range from 2,000 nanometers to 20,000 nanometers.

As depicted in FIG. 1, metrology system 100 includes an illumination subsystem configured to direct illumination light 117 to one or more structures formed on the wafer 120 at an angle of incidence, α, defined with reference to an axis normal to the surface of wafer 120, e.g., the Z-axis depicted in FIG. 1. The illumination subsystem is shown to include light source 110, one or more optical filters 111, polarizing component 112, field stop 113, aperture stop 114, and illumination optics 115. The one or more optical filters 111 are used to control light level, spectral output, or both, from the illumination subsystem. In some examples, one or more multi-zone filters are employed as optical filters 111. Polarizing component 112 generates the desired polarization state exiting the illumination subsystem. In some embodiments, the polarizing component is a polarizer, a compensator, or both, and may include any suitable commercially available polarizing component. The polarizing component can be fixed, rotatable to different fixed positions, or continuously rotating. Although the illumination subsystem depicted in FIG. 1 includes one polarizing component, the illumination subsystem may include more than one polarizing component. Field stop 113 controls the field of view (FOV) of the illumination subsystem and may include any suitable commercially available field stop. Aperture stop 114 controls the numerical aperture (NA) of the illumination subsystem and may include any suitable commercially available aperture stop. Light from illumination source 110 is directed through illumination optics 115 to be focused on one or more structures (not shown in FIG. 1) on wafer 120. The illumination subsystem may include any type and arrangement of optical filter(s) 111, polarizing component 112, field stop 113, aperture stop 114, and illumination optics 115 known in the art of spectroscopic ellipsometry, reflectometry, and scatterometry.

As depicted, in FIG. 1, the beam of illumination light 117 passes through optical filter(s) 111, polarizing component 112, field stop 113, aperture stop 114, and illumination optics 115 as the beam propagates from the illumination source 110 to wafer 120. Beam 117 illuminates a portion of wafer 120 over a measurement spot 116.

Metrology system 100 also includes a collection optics subsystem configured to collect light generated by the interaction between the one or more structures and the incident illumination beam 117. A beam of collected light 127 is collected from measurement spot 116 by collection optics 122. Collected light 127 passes through collection aperture stop 123, polarizing element 124, and field stop 125 of the collection optics subsystem.

Collection optics 122 includes any suitable optical elements to collect light from the one or more structures formed on wafer 120. Collection aperture stop 123 controls the NA of the collection optics subsystem. Polarizing element 124 analyzes the desired polarization state. The polarizing element 124 is a polarizer or a compensator. The polarizing element 124 can be fixed, rotatable to different fixed positions, or continuously rotating. Although the collection subsystem depicted in FIG. 1 includes one polarizing element, the collection subsystem may include more than one polarizing element. Collection field stop 125 controls the field of view of the collection subsystem. The collection subsystem takes light from wafer 120 and directs the light through collection optics 122, and polarizing element 124 to be focused on collection field stop 125. In some embodiments, collection field stop 125 is used as a spectrometer slit for the spectrometers of the detection subsystem. In other embodiments, collection field stop 125 may be located at or near a spectrometer slit of the spectrometers of the detection subsystem.

The collection subsystem may include any type and arrangement of collection optics 122, aperture stop 123, polarizing element 124, and field stop 125 known in the art of spectroscopic ellipsometry, reflectometry, and scatterometry.

In the embodiment depicted in FIG. 1, the collection optics subsystem directs light to spectrometer 126. Spectrometer 126 generates output responsive to light collected from the one or more structures illuminated by the illumination subsystem. In one example, the detectors of spectrometer 126 are charge coupled devices (CCD) sensitive to ultraviolet and visible light (e.g., light having wavelengths between 190 nanometers and 860 nanometers). In other examples, one or more of the detectors of spectrometer 126 is a photo detector array (PDA) sensitive to infrared light (e.g., light having wavelengths between 950 nanometers and 2500 nanometers). However, in general, other detector technologies may be contemplated (e.g., a position sensitive detector (PSD), an infrared detector, a photovoltaic detector, a quadrature cell detector, a camera, etc.). Each detector converts the incident light into electrical signals indicative of the spectral intensity of the incident light. In general, spectrometer 126 generates output signals 128 indicative of the spectral response of the structure under measurement to the illumination light.

Metrology system 100 also includes computing system 130 configured to receive signals 128 indicative of the measured spectral response of the structure of interest and estimate values 129 of one or more parameters of interest characterizing the one or more structures under measurement, e.g., film thickness, critical dimensions, overlay, etc., based on the measured spectral response. Signals 128 indicative of the measured spectral response of the structure of interest are collected at both an unperturbed and a perturbed orientation of semiconductor wafer 120 at the measurement site as described herein.

Wafer stage 140 positions wafer 120 with respect to the ellipsometer subsystem 101. In some embodiments, wafer stage 140 moves wafer 120 in the XY plane by combining two orthogonal, translational movements (e.g., movements in the X and Y directions) to position wafer 120 with respect to the ellipsometer. In some embodiments, wafer stage 140 is configured to control the location of wafer 120 with respect to the illumination provided by the optical ellipsometer in six degrees of freedom. In general, specimen positioning system 140 may include any suitable combination of mechanical elements to achieve the desired linear and angular positioning performance, including, but not limited to goniometer stages, magnetically levitated stages, hexapod stages, angular stages, and linear stages. Computing system 130 is communicatively coupled to wafer stage 140 and communicates motion command signals 141 to wafer stage 140. In response, wafer stage 140 positions wafer 120 with respect to the ellipsometer in accordance with the motion control commands.

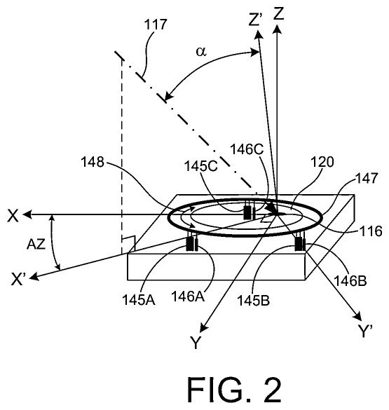

FIG. 2 is a diagram illustrative of some elements of wafer stage 140 depicted in FIG. 1. Wafer 120 is removably attached to wafer chuck 147 of wafer stage 140, e.g., using a vacuum clamp, electrostatic clamp, edge grip clamp, etc. In the embodiment depicted in FIGS. 1 and 2, wafer stage 140 is configured to control the effective angle of incidence of illumination beam 117 onto one or more structures disposed at any desired location on wafer 120.

In the embodiment depicted in FIGS. 1 and 2, the effective angle of incidence is characterized by the angle of incidence, α, and the azimuth angle, Az. Together, the angle of incidence and the azimuth angle define the effective angle of incidence of illumination beam 117 with respect wafer 120. Wafer stage 140 is configured to position wafer 120 with respect to illumination beam 117 at both unperturbed and perturbed angles of incidence, azimuth angle, or both.

In general, an orientation of illumination beam 117 relative to the surface normal of semiconductor wafer 120 is described by any two angular positions of wafer 101 with respect to the illumination beam 117, or vice-versa. In one example, the orientation is described with respect to a coordinate system fixed to the wafer. FIGS. 1 and 2 depict illumination beam 117 incident on wafer 120 at a particular orientation described by an angle of incidence, θ, and an azimuth angle, Az. Coordinate frame XYZ is fixed to the metrology system (e.g., illumination beam 117) and coordinate frame X′Y′Z′ is fixed to wafer 120. The Z′ axis is an axis normal to the surface of wafer 120 at measurement spot 116, and X′ and Y′ are in a plane aligned with the surface of wafer 120. Angle of incidence, a, describes the orientation of the illumination beam 117 with respect to the surface normal of the wafer in the X′Z′ plane. Furthermore, azimuth angle, Az, describes the orientation of the XZ plane with respect to the X′Z′ plane. Together, α and Az, uniquely define the orientation of the illumination beam 117 with respect to the surface of wafer 120.

In this example, a change in orientation of the illumination beam with respect to the surface of wafer 120, i.e., a change in effective angle of incidence, is described by a change in azimuth angle induced by a rotation about an axis normal to the surface of wafer 120 (i.e., Z′ axis), a change in angle of incidence induced by a rotation about an axis aligned with the surface of wafer 120 (i.e., Y′ axis), or both.

As depicted in FIGS. 1-2, wafer stage 140 includes a base frame 142, an X-stage 143, a Y-stage 144, a three degree of freedom wafer stage, and a rotational stage supporting wafer chuck 147. In some embodiments, base frame 142 is mechanically coupled to a machine frame to which the measurement subsystem, e.g., ellipsometer 101, is also mechanically coupled. X-stage 143 is mechanically constrained by a bearing assembly, e.g., mechanical, magnetic, or air bearings, to move freely in X direction with respect to base frame 142. One or more actuators, e.g., linear motors, (not shown) are employed to control the position of X-stage 143 with respect to base frame 142 in the X direction. Similarly, Y-stage 144 is mechanically constrained by a bearing assembly, e.g., mechanical, magnetic, or air bearings, to move freely in Y direction with respect to X-stage 143. One or more actuators, e.g., linear motors, (not shown) are employed to control the position of Y-stage 144 with respect to X-stage 143 in the Y direction. As depicted in FIGS. 1 and 2, Y-stage 144 is stacked on X-stage 143. Together, X-stage 143 and Y-stage 144 provide a long stroke capability, i.e., workspace of at least 300 millimeters in the X and Y directions, such that X-stage 143 and Y-stage 144 are controlled to position any location on the surface of wafer 120 under measurement spot 116 defined by the optical elements of ellipsometer 101.

In the embodiment depicted in FIGS. 1 and 2, the three degree of freedom wafer stage, a.k.a., the tip-tilt-Z stage, includes actuators 145A-C, e.g., voice coil motors, piezoelectric motors, etc.). Each of actuators 145A-C is mechanically coupled between the wafer chuck 147 and Y-stage 144. The direction of extent of each of actuators 145A-C is approximately parallel to the Z axis, i.e., an axis aligned with the Z′ axis in a nominal orientation of wafer 120. As depicted in FIGS. 1 and 2, actuators 145A-C are spaced apart from one another in the X and Y directions. In this configuration, the movements of actuators 145A-C are coordinated to independently control the position of wafer 120 in the Z-direction, the orientation of wafer 120 about the X axis, and the orientation of wafer 120 about the Y axis. For known azimuth angle, the movements of actuators 145A-C are coordinated to independently control the position of wafer 120 in the Z-direction, the orientation of wafer 120 about the X′ axis, and the orientation of wafer 120 about the Y′ axis. More specifically, rotational movements about the Y′-axis control the angle of incidence, α. In other words, rotational movements about the Y′-axis tilt the wafer perpendicular to the plane of incidence of the illumination beam 117. Movements of wafer 120 specified in {R_{x′}, R_{y′}, Z′} coordinates map to movements of actuators 145A-C by a simple kinematic transformation characterized by the geometric distances between actuators 145A-C in the {X′,Y′,Z′} coordinate frame. In this manner, control commands 141 specifying movements in {R_{x′}, R_{y′}, Z′} coordinates are readily mapped to movements of each actuator. The movements of each actuator are implemented at the actuator level by one or more motion controllers of wafer stage 140.

Similarly, position measurement devices 146A-C, e.g., linear encoders, linear variable differential transformers, inductive probes, capacitive probes, interferometers, etc.) are spaced apart from one another in the X′ and Y′ directions. In this configuration, the position of wafer 120 with respect to Y-stage 144 in the Z-direction, the orientation of wafer 120 about the X′ axis, and the orientation of wafer 120 about the Y′ axis are captured by position measurement devices 146A-C. The displacements captured by position measurement devices 146A-C map to displacements of wafer 120 expressed in the {R_{x′}, R_{y′}, Z′} coordinates by a simple kinematic transformation characterized by the geometric distances between position measurement devices 146A-C and the {X′,Y′,Z′} coordinate frame. In this manner, displacements measured by position measurement devices 146A-C are readily mapped to displacements in {R_{x′}, R_{y′}, Z′} coordinates. The displacements are communicated to computing system 130 for measurements at unperturbed and perturbed orientations as described herein. In some embodiments, the displacements are communicated to one or motion controllers of wafer stage 140 to implement a feedback positioning controller that locates wafer 120 at a desired position and orientation based on measurements by position measurement devices 146A-C.

In some embodiments, position measurement devices 146A-C are co-located with actuators 145A-C. Each of the position sensors is located in close proximity to a corresponding actuator, and thus measures a displacement in the direction of extent of each corresponding actuator. However, in general, position measurement devices 146A-C may be located in different locations than actuators 145A-C.

Wafer stage 140 illustrated in FIG. 2 also includes a wafer stage having three actuators to generate force in the Z-direction at three different locations to control three degrees of freedom of wafer 120. However, in general, a wafer stage may include more than three actuators to generate force in the Z direction at more than three locations to control the three degrees of freedom of wafer 120. Although, such configurations are over-constrained, it may be desirable to include more than three actuators to limit the force requirements on any one actuator, stabilize bending modes in wafer chuck 147, operate in coordination as part of a magnetically levitated wafer chuck 147, etc.

In addition, wafer stage 140 includes a rotational stage 148 mounted to the tip-tilt-Z stage including actuators 145A-C. Rotational stage 148 rotates wafer chuck 147 with respect to the tip-tilt-Z stage. Rotational stage 148 includes a rotational actuator (not shown) to rotate wafer chuck 147 with respect to the tip-tilt-Z stage. In some examples, the rotational actuator is a rotary motor. In addition, rotational stage 148 includes a rotational displacement sensor (not shown) to measure the orientation of wafer chuck 147 with respect to the tip-tilt-Z stage. In some examples, the rotational displacement sensor is a rotational encoder. In this configuration, the rotational movement of the rotational actuator of rotational stage 148 independently controls the rotational orientation of wafer 120 about the Z′ axis with respect to base frame 142. As such, rotational stage 148 controls the azimuth angle of wafer 120.

As illustrated in FIGS. 1 and 2, metrology system 100 includes a wafer positioning system 140 configured to both align wafer 120 and orient wafer 120 over a range of angles of incidence and azimuth angle with respect the illumination beam 117. In this manner, measurements of wafer 120 are collected by metrology system 100 over any number of locations and orientations on the surface of wafer 120. In one example, computing system 130 communicates command signals 141 to wafer positioning system 140 that indicate the desired position and orientation of wafer 120. In response, wafer positioning system 140 generates command signals to the various actuators of wafer positioning system 140 to achieve the desired positioning of wafer 120.

In general, wafer positioning system 140 may include any suitable combination of mechanical elements to achieve the desired linear and angular positioning performance, including, but not limited to goniometer stages, hexapod stages, angular stages, and linear stages.

In general, an optical scatterometer, such as metrology system 100 is configured to deliver illumination light to a metrology target under measurement at any desired angle of incidence and azimuth angle.

In some embodiments, signal multiplexing is employed to measure multiple wavelengths simultaneously to reduce signal acquisition time. During each measurement, the detection system simultaneously measures each dispersed beam with a multiplexed readout of signals from the detectors. Furthermore, the detection system calculates the spectral signal from the signals at each wavelength.

Collected light is spatially dispersed across a detector array according to wavelength. Light from each narrow band of wavelengths is incident on a different pixel of the detector array. The detected light signal at each narrow band of wavelengths is measured simultaneously by a multiplexed readout of the pixels.

In general, the detected measurement signals depend on the configuration of the measurement subsystem. In some embodiments, the detected measurement signals are spectroscopic ellipsometry (SE) harmonic signals, e.g., {α,β}, {ψ,Δ}, etc. In some embodiments the detected SE measurement signals are one or more elements of the Mueller Matrix representation of the SE measurement. In general, any detected SE measurement signal sensitive to changes in optical properties due to effective incidence angle may be contemplated within the scope of this patent document.

In one aspect, spectral measurements of a structure of interest at both an unperturbed effective illumination angle and a perturbed effective illumination angle are collected and employed to estimate a value of at least one parameter of interest characterizing the structure of interest.

In some embodiments, metrology system 100 also includes computing system 130 configured as a perturbation based measurement engine 160 configured to estimated values of one or more parameters of interest characterizing a structure under measurement based on changes in measurement signal values induced by changes in the effective illumination angle.

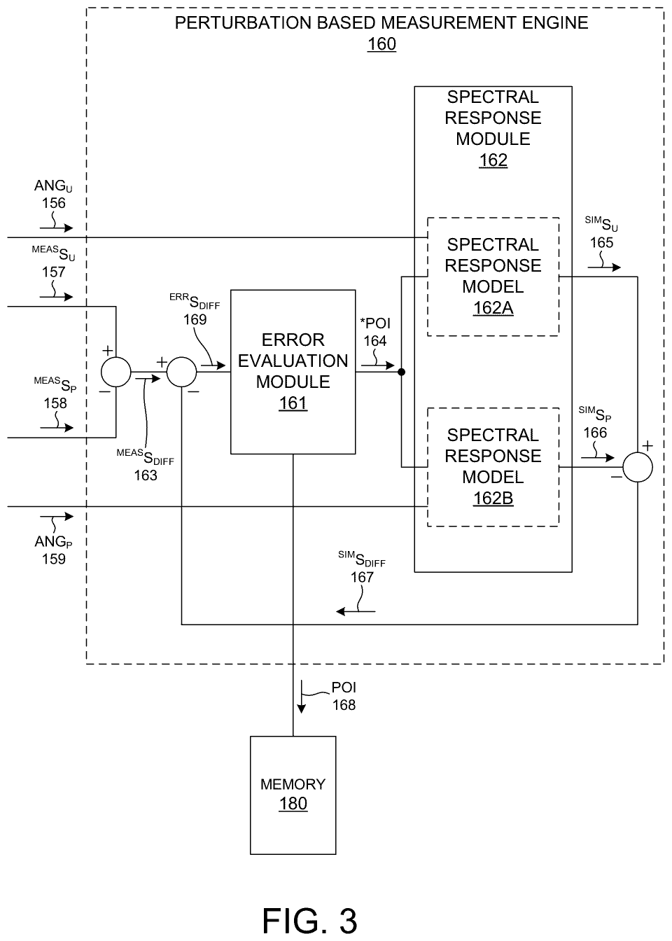

FIG. 3 is a diagram illustrative of perturbation based measurement engine 160 in one embodiment. As depicted in FIG. 3, perturbation based measurement engine 160 includes an error evaluation module 161 and a spectral response module 162. Perturbation based measurement engine 160 receives measurement signals, ^{MEAS}S_{U} 157, associated with measurements performed in an unperturbed orientation of one or more structures under measurement with respect to the illumination beam and measurement signals, ^{MEAS}S_{P} 158, associated with measurements performed in a perturbed orientation of the one or more structures under measurement with respect to the illumination beam. Perturbation based measurement engine 160 determines a difference, ^{MEAS}S_{DIFF} 163, between the perturbed measurement signals, ^{MEAS}S_{P} 158, and the unperturbed measurement signals, ^{MEAS}S_{U} 157. Spectral response module 162 receives the measured orientation of the structures under measurement with respect to the illumination beam for both the unperturbed orientation, ANG_{U}156, and the perturbed orientation, ANG_{P} 159. In some embodiments, the measured orientation of the structures under measurement with respect to the illumination beam is provided by the specimen positioning system 140. Spectral response module 162 includes a spectral response model that simulates the expected values of the measurement signals detected by the metrology system, e.g., metrology system 100, for a given set of values of floating model parameters and measurement system parameters, e.g., orientation of the one or more structures under measurement with respect to the illumination beam. Spectral response module 162 includes two different instances of the spectral response model. In the embodiment depicted in FIG. 3, spectral response model 162A simulates the unperturbed measurement signals, ^{SIM}S_{U} 165, based on the unperturbed orientation, ANG_{U} 156, and the assumed values, *POI 164, of the one or more parameters of interest characterizing the one or more structures under measurement. Similarly, spectral response model 162B simulates the perturbed measurement signals, ^{SIM}S_{P} 166, based on the perturbed orientation, ANG_{P} 159, and the assumed values, *POI 164, of the one or more parameters of interest characterizing the one or more structures under measurement.

Perturbation based measurement engine 160 determines a difference, ^{SIM}S_{DIFF} 167, between the simulated, perturbed measurement signals, ^{SIM}S_{P} 166, and the simulated, unperturbed measurement signals, ^{SIM}S_{U} 165. In addition, perturbation based measurement engine 160 determines a set of error signals, ^{ERR}S_{DIFF} 169, as the difference between the simulated, difference signals, ^{SIM}S_{DIFF} 167, and the measured, difference signals, ^{MEAS}S_{DIFF} 163. The computed set of error signals, ^{ERR}S_{DIFF} 169, is communicated to error evaluation module 161. Error module 161 determines updated values of the assumed values, *POI 164, of the one or more parameters of interest characterizing the one or more structures under measurement. Perturbation based measurement engine 160 iterates until error signals, ^{ERR}S_{DIFF} 169, are minimized, e.g., fall below a predetermined threshold. After the iteration is complete, the current values of the one or more parameters of interest characterizing the one or more structures under measurement, POI 168, are stored in memory 180.

In some embodiments, metrology system 100 also includes computing system 130 configured as a derivative estimation engine 150 configured to determine at least one derivative of the detected measurement signals with respect to the effective illumination angle.

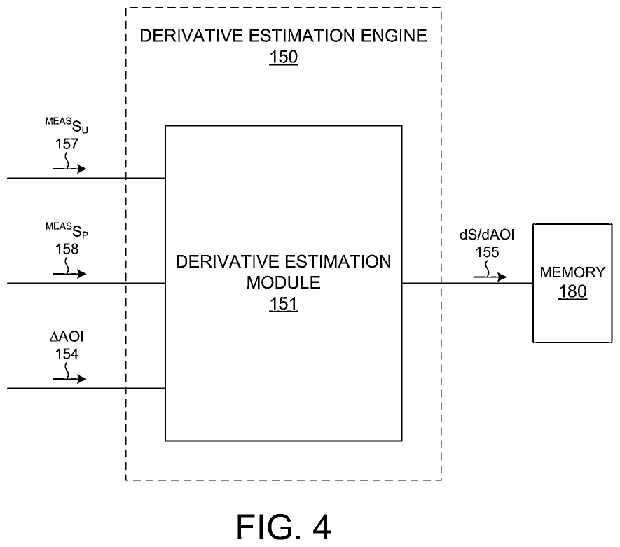

FIG. 4 is a diagram illustrative of a derivative estimation engine 150 in one embodiment. As depicted in FIG. 4, derivative estimation engine 150 includes a derivative estimation module 151. Derivative estimation engine 150 receives measurement signals, ^{MEAS}S_{U} 157, associated with measurements performed in an unperturbed orientation of one or more structures under measurement with respect to the illumination beam and measurement signals, ^{MEAS}S_{P} 158, associated with measurements performed in a perturbed orientation of the one or more structures under measurement with respect to the illumination beam. In addition, derivative estimation engine 150 receives a difference, ΔAOI 154, between the unperturbed orientation, ANG_{U} 156, and the perturbed orientation, ANG_{P} 159. Derivative estimation module 151 determines a first derivative, dS/dAOI 155, of the detected measurement signals with respect to the effective illumination angle based on measurement signals, ^{MEAS}S_{U} 157, measurement signals, ^{MEAS}S_{P} 158, and the difference in orientation, ΔAOI 154, between the unperturbed and perturbed orientations. In some embodiments, derivative estimation module 151 employs a finite difference algorithm to approximate the derivative based on the difference between the perturbed and unperturbed measurement signals and the difference in orientation.

Although FIG. 4 depicts a derivative estimation engine 150 configured to determine a first derivative of the detected measurement signals with respect to the effective illumination angle, in general, derivative estimation engine 150 may be configured to determine higher order derivatives of detected measurement signals with respect to the effective illumination angle. In some examples, derivative estimation engine 150 employs a finite difference algorithm to estimate higher order derivatives of detected measurement signals with respect to the effective illumination angle. In general, additional measurements are performed at different perturbed orientations about the unperturbed orientation to provide the necessary measurement data to determine a higher order derivative of detected measurement signals with respect to the effective illumination angle. In one example, two different perturbed orientations are measured above the unperturbed orientation and two different perturbed orientations are measured below the unperturbed orientation. In this example, derivative estimation module employs a finite difference algorithm to determine a second order derivative of detected measurement signals with respect to the effective illumination angle based on the unperturbed measurement signals, the measurement signals collected at the four different perturbed orientations and the corresponding perturbed orientations. Similarly, derivative estimation module employs a finite difference algorithm to determine an Nth order derivative of detected measurement signals with respect to the effective illumination angle based on the unperturbed measurement signals, the measurement signals collected at the N different perturbed orientations measured above the unperturbed orientation, the N different perturbed orientations are measured below the unperturbed orientation, and the corresponding perturbed orientations.

In some embodiments, metrology system 100 also includes computing system 130 configured as a derivative based measurement engine 170 configured to estimate values of one or more parameters of interest characterizing a structure under measurement based on at least one derivative of the detected measurement signals with respect to the effective illumination angle, which in turn, is determined based on changes in measurement signal values induced by changes in the effective illumination angle as described with reference to FIG. 4. In these embodiments, derivative signals, e.g., derivative spectra, are additional data quantities employed to fit a structural measurement model to the measured signals. In general, the additional derivative signals help to break correlations between model parameters, improve measurement precision and accuracy, reduce computational effort required to converge on a solution, etc.

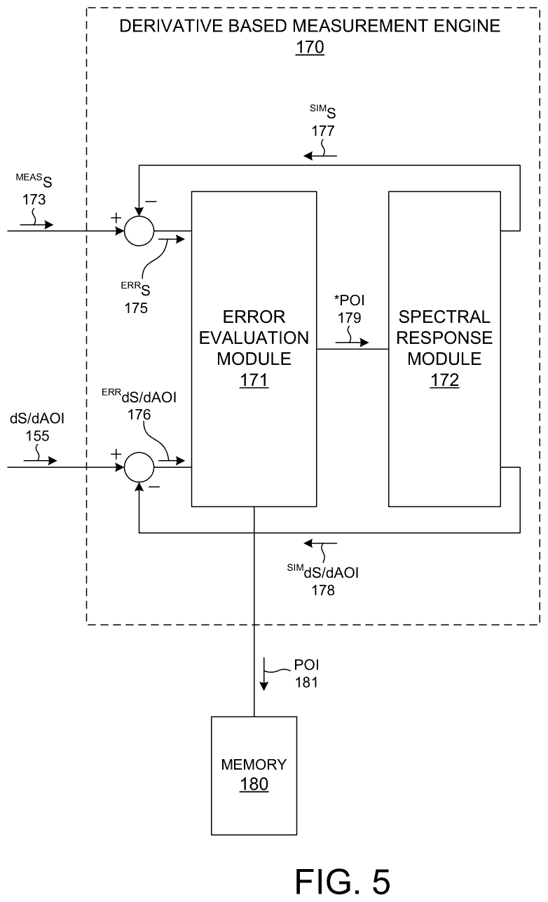

FIG. 5 is a diagram illustrative of derivative based measurement engine 170 in one embodiment. As depicted in FIG. 5, derivative based measurement engine 170 includes an error evaluation module 171 and a spectral response module 172. Derivative based measurement engine 170 receives derivative measurement signals with respect to the effective illumination angle, such as the derivative signals, dS/dAOI 155, described with reference to FIG. 4. In addition, derivative based measurement engine receives measurement signals, ^{MEAS}S 173, associated with measurements of the one or more structures under measurement by the metrology system, e.g., metrology system 100. In some examples, the measurement signals, ^{MEAS}S 173, are associated with measurements at the unperturbed orientation, the perturbed orientation, or both. In some examples, the measurement signals, ^{MEAS}S 173, are associated with measurements at one or more different orientations.

Spectral response module 172 includes a spectral response model that simulates the expected values of the measurement signals, ^{SIM}S 177, and derivative measurement signals, ^{SIM}dS/dAOI 178 associated with a measurement of the one or more structures by the metrology system, e.g., metrology system 100, for a given set of values of floating model parameters, *POI 179, including the one or more parameters of interest characterizing the one or more structures under measurement.

Derivative based measurement engine 170 determines a set of error signals, ^{ERR}S 175, as the difference between the simulated measurement signals, ^{SIM}S 177, and the measured signals, ^{MEAS}S 173. The computed set of error signals, ^{ERR}S 175, is communicated to error evaluation module 171. In addition, derivative based measurement engine 170 determines a set of error signals, ^{ERR}dS/dAOI 176, as the difference between the simulated, derivative signals, ^{SIM}dS/dAOI 178, and the measured, derivative signals, dS/dAOI 155. The computed set of error signals, ^{ERR}dS/dAOI 176, is communicated to error evaluation module 171. Error module 171 determines updated values of the assumed values, *POI 179, of the one or more parameters of interest characterizing the one or more structures under measurement based on the set of error signals, ^{ERR}S 175, and the set of error signals, ^{ERR}dS/dAOI 176. Derivative based measurement engine 170 iterates until error signals, ^{ERR}S 175 and ^{ERR}dS/dAOI 176, are minimized, e.g., fall below predetermined thresholds. After the iteration is complete, the current values of the one or more parameters of interest characterizing the one or more structures under measurement, POI 181, are stored in memory 180.

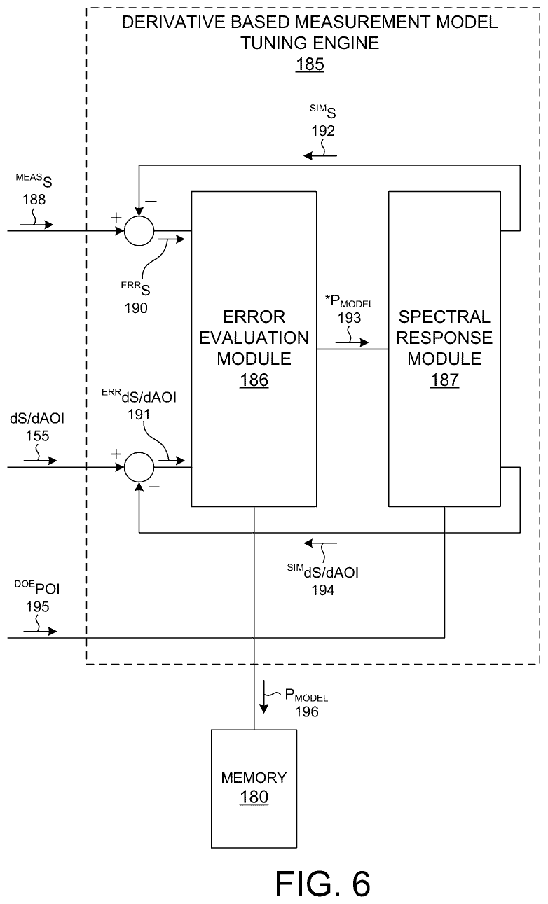

FIG. 6 is a diagram illustrative of derivative based measurement model tuning engine 185 in one embodiment. As depicted in FIG. 6, derivative based measurement model tuning engine 185 includes an error evaluation module 186 and a spectral response module 187. Derivative based measurement model tuning engine 185 receives derivative measurement signals with respect to the effective illumination angle, such as the derivative signals, dS/dAOI 155, described with reference to FIG. 4. In addition, derivative based measurement model tuning engine 185 receives measurement signals, ^{MEAS}S 188, associated with measurements of the one or more structures under measurement by the metrology system, e.g., metrology system 100. In some examples, the measurement signals, ^{MEAS}S 188, are associated with measurements at the unperturbed orientation, the perturbed orientation, or both. In some examples, the measurement signals, ^{MEAS}S 188, are associated with measurements at one or more different orientations.

Spectral response module 187 includes a spectral response model that simulates the expected values of the measurement signals, ^{SIM}S 192, and derivative measurement signals, ^{SIM}dS/dAOI 194 associated with a measurement of the one or more structures by the metrology system, e.g., metrology system 100, for a set of trusted values of one or more parameters of interest, ^{DOE}POI 195, characterizing one or more structures under measurement and a given set of values of floating model parameters, *P_{MODEL} 193, including model parameters subject to tuning. The model parameters subject to tuning are typically maintained as fixed valued variables when performing model based measurement of one or more parameters of interest characterizing one or more structures under measurement.

Derivative based measurement model tuning engine 185 determines a set of error signals, ^{ERR}S 190, as the difference between the simulated measurement signals, sIMS 192, and the measured signals, ^{MEAS}S 188. The computed set of error signals, ^{ERR}S 190, is communicated to error evaluation module 171. In addition, derivative based measurement model tuning engine 185 determines a set of error signals, ^{ERR}dS/dAOI 191, as the difference between the simulated, derivative signals, ^{SIM}dS/dAOI 194, and the measured, derivative signals, dS/dAOI 155. The computed set of error signals, ^{ERR}dS/dAOI 191, is communicated to error evaluation module 171. Error evaluation module 171 determines updated values of the model parameters subject to tuning, *P_{MODEL} 193, based on the set of error signals, ^{ERR}S 190, and the set of error signals, ^{ERR}dS/dAOI 191. Derivative based measurement model tuning engine 185 iterates until error signals, ^{ERR}S 190 and ^{ERR}dS/dAOI 191, are minimized, e.g., fall below predetermined thresholds. After the iteration is complete, the current values of the model parameters, P_{MODEL} 196, are stored in memory 180.

In the embodiments depicted in FIGS. 5 and 6, derivative based measurement engine 170 and derivative based measurement model tuning engine 185 employ iterative regression to fit a structural measurement model to the measured signals and derivative signals generated from measurement signals acquired at two or more different orientations. In some other embodiments, a derivative based measurement engine, a derivative based measurement model tuning engine, or both, employ iterative regression to fit a structural measurement model to only the derivative signals generated from measurement signals acquired at two or more different orientations.

In general, a derivative based measurement engine, a derivative based measurement model tuning engine, or both, may employ iterative regression to fit a structural measurement model to any combination of measured signals and derivative signals, e.g., first order derivative signals, higher order derivative signals, or both, generated from measurement signals acquired at two or more different orientations.

In some embodiments, metrology system 100 also includes computing system 130 configured as a perturbation based measurement model evaluation engine 200. Perturbation based measurement model evaluation engine 200 quantifies the fitting performance of a measurement model for measurements performed at both unperturbed and perturbed orientations of a structure under measurement with respect to the illumination beam. The measured fitting performance may be used to determine whether the measurement model requires structural changes, additional parameter tuning, or both, before implementation in a production scenario.

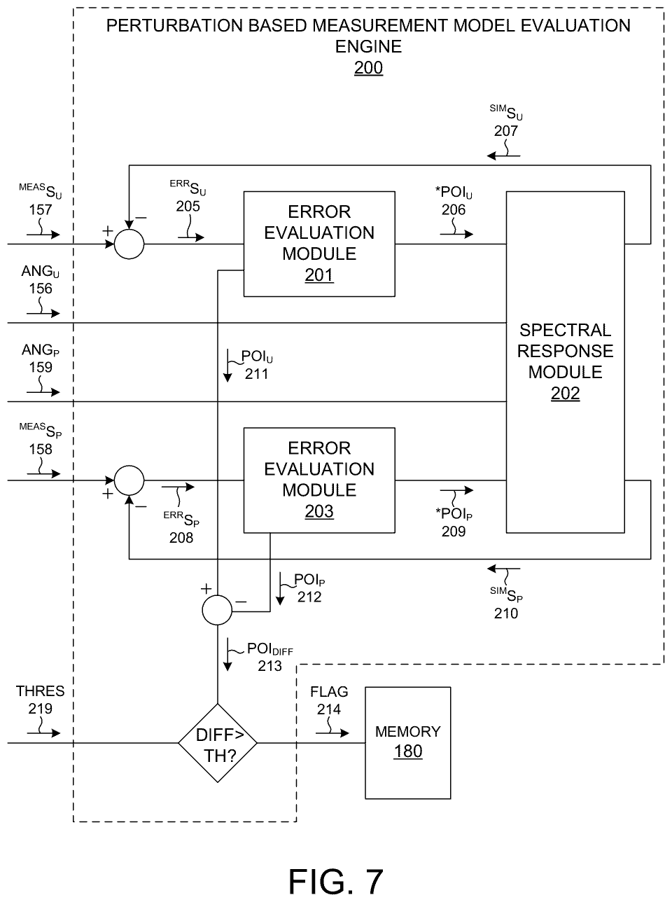

FIG. 7 is a diagram illustrative of perturbation based measurement model evaluation engine 200 in one embodiment. As depicted in FIG. 7, perturbation based measurement model evaluation engine 200 includes error evaluation modules 201 and 203 and spectral response module 202. Perturbation based measurement model evaluation engine 200 receives measurement signals, ^{MEAS}S_{U} 157, associated with measurements performed in an unperturbed orientation of one or more structures under measurement with respect to the illumination beam and measurement signals, ^{MEAS}S_{P} 158, associated with measurements performed in a perturbed orientation of the one or more structures under measurement with respect to the illumination beam. Spectral response module 202 receives the measured orientation of the structures under measurement with respect to the illumination beam for both the unperturbed orientation, ANG_{U} 156, and the perturbed orientation, ANG_{P} 159. In some embodiments, the measured orientation of the structures under measurement with respect to the illumination beam is provided by the specimen positioning system 140.

Spectral response module 202 includes a spectral response model that simulates the expected values of the measurement signals detected by the metrology system, e.g., metrology system 100, for a given set of values of floating model parameters and measurement system parameters, e.g., orientation of the one or more structures under measurement with respect to the illumination beam. In the embodiment depicted in FIG. 7, spectral response module 202 simulates the unperturbed measurement signals, ^{SIM}S_{U} 207, based on the unperturbed orientation, ANG_{U} 156, and the assumed values, *POI_{U} 206, of the one or more parameters of interest characterizing the one or more structures under measurement. Similarly, spectral response model 202 simulates the perturbed measurement signals, ^{SIM}S_{P} 210, based on the perturbed orientation, ANG_{P} 159, and the assumed values, *POI_{P} 209, of the one or more parameters of interest characterizing the one or more structures under measurement.

Perturbation based measurement model evaluation engine 200 determines a set of error signals, ^{ERR}S_{U} 205, as the difference between the simulated unperturbed signals, ^{SIM}S_{U} 207, and the measured unperturbed signals, ^{MEAS}S_{U} 157. The computed set of error signals, ^{ERR}S_{U} 205, is communicated to error evaluation module 201. Error evaluation module 201 determines updated values of the assumed values, *POI_{U} 206, of the one or more parameters of interest characterizing the one or more structures under measurement as evaluated based on unperturbed measurement signals. Perturbation based measurement model evaluation engine 200 iterates until error signals, ^{ERR}S_{U} 205, are minimized, e.g., fall below a predetermined threshold.

In addition, perturbation based measurement model evaluation engine 200 determines a set of error signals, ^{ERR}S_{P} 208, as the difference between the simulated perturbed signals, ^{SIM}S_{P} 210, and the measured perturbed signals, ^{MEAS}S_{P} 158. The computed set of error signals, ^{ERR}S_{P} 208, is communicated to error evaluation module 203. Error evaluation module 203 determines updated values of the assumed values, *POI_{P} 209, of the one or more parameters of interest characterizing the one or more structures under measurement as evaluated based on perturbed measurement signals. Perturbation based measurement model evaluation engine 200 iterates until error signals, ^{ERR}S_{P} 208, are minimized, e.g., fall below a predetermined threshold.

After the iteration is complete, a difference, POI_{DIFF} 213, between the current values of the one or more parameters of interest characterizing the one or more structures under measurement, POI_{U} 211, as determined based on unperturbed measurement signals and the current values of the one or more parameters of interest characterizing the one or more structures under measurement, POI_{P} 212, as determined based on perturbed measurement signals, is calculated. The difference, POI_{DIFF} 213, indicates how closely the measurement model estimates the values of one or more parameters of interest characterizing the same structure under measurement as evaluated based on both unperturbed and perturbed measurement signals.

In the embodiment depicted in FIG. 7, the calculated difference is compared to a predetermined threshold value, THRES 219. If the difference is greater than THRES 219, a flag 214 is set indicating that the model under evaluation is not sufficiently accurate. If the difference is less than THRES 219, flag 214 is set indicating that the model under evaluation is sufficiently accurate. Flag 214 is stored in memory 180.

In general, the SE metrology system described with reference to FIG. 1 may be any form of a spectroscopic ellipsometer including, but not limited to, a rotating compensator SE system, a rotating polarizer SE system, a rotating polarizer, rotating compensator SE system, a rotating compensator, rotating compensator SE system, etc. In addition, the perturbation based measurement techniques may be applied to other ellipsometric systems that employ non-rotating, solid state devices such as photo-elastic modulators to measure all or a portion of the sample Mueller matrix.

In general, the measurement signals are perturbed by inducing changes effective illumination angle of the measurement target under measurement. As described hereinbefore, the changes in the effective illumination angle are induced by changing the orientation of the wafer with respect to the illumination beam. However, in general, any suitable technique for changing the effective illumination angle is contemplated within the scope of this patent document. In some embodiments, the effective illumination angle is changed by reorienting the illumination beam with respect to the wafer, for example, using an illumination beam positioning system employed to change the orientation of the illumination source with respect to the wafer. In another example, an illumination beam positioning system employs one or more actuators configured to move one or more optical elements in the illumination beam path between the illumination source and the wafer to change the orientation of the illumination beam with respect to the wafer.

The methods and systems described herein enable improved measurements of structural elements common in semiconductor manufacturing, e.g., material composition, alloy fraction measurements of compound semiconductors, material band gap, characterization of semiconductor surfaces and interfaces, film layer properties, critical dimensions, etc. Measurement applications include measurements of structural elements comprising complex semiconductor structures such as 3D VNAND structures and Gate-All-Around (GAA) structures, including front-end-of-line (FEOL) layers from oxide definition layers to high-k metal gate (HKMG) stacks. Measurement applications include measurements of structural elements comprised of semiconducting materials, insulating dielectric materials, and conducting materials, including organic materials, inorganic materials, or a combination thereof.

In general, the magnitude of the perturbation of the effective illumination angle is selected for each measurement application to improve sensitivity and reduce correlations.

In general, the techniques to break correlations among various contributors to the measured optical response described herein may be combined to improve the accuracy of measurements of complex semiconductor structures. For example, derivative based measurements of structures at various wavelengths, angles of incidence, azimuth angles, or any combination thereof can be analyzed sequentially or in parallel to accurately decorrelate structural features associated with complex multi-layer structures.

In a further aspect, the wavelengths emitted by the measurement illumination source, e.g., illumination source 110, are selectable. In some embodiments, illumination source 110 is a LSP light source controlled by computing system 130 to maximize flux in one or more selected spectral regions. Laser peak intensity at the target material controls the plasma temperature and thus the spectral region of emitted radiation. Laser peak intensity is varied by adjusting pulse energy, pulse width, or both. As depicted in FIG. 1, computing system 130 communicates command signal 141 to illumination source 110 that causes illumination source 110 to adjust the spectral range of wavelengths emitted from illumination source 110. In one example, illumination source 110 is a LSP light source and the LSP light source adjusts any of a pulse duration, pulse frequency, and target material composition to realize a desired spectral range of wavelengths emitted from the LSP light source.

In some examples, any of the measurement engines depicted in FIGS. 3-7 read a file that contains the equations describing the shape and composition of the structure under measurement. In some examples, this file is generated by a lithography simulator such as PROLITH software available from KLA Corporation, Milpitas, California (USA). Based on this application information the measurement engine automatically sets the parameterization and constraints of the structural model.

Although the methods described herein are explained with reference to system 100, any optical or x-ray based metrology system configured to illuminate and detect light scattered from a specimen may be employed to implement the exemplary methods described herein. Furthermore, any electron based metrology system configured to illuminate and detect scattered electrons from a specimen may be employed to implement the exemplary methods described herein. Exemplary systems include an angle-resolved reflectometer (i.e., a beam profile reflectometer), an angle-resolved ellipsometer (i.e., beam profile ellipsometer), a scatterometer, a spectroscopic reflectometer or ellipsometer, a spectroscopic reflectometer or ellipsometer with multiple angles of illumination, a Mueller Matrix spectroscopic ellipsometer (e.g., a rotating compensator spectroscopic ellipsometer), a single wavelength ellipsometer, a single wavelength reflectometer, a RAMAN scatterometer, a transmission, small-angle x-ray scatterometer, a reflective, small-angle x-ray scatterometer, a grazing incidence, small-angle x-ray scatterometer, a transmission electron microscope, a scanning electron microscope, etc.

By way of non-limiting example, an ellipsometer may include a single rotating compensator, multiple rotating compensators, a rotating polarizer, a rotating analyzer, a modulating element, multiple modulating elements, or no modulating element.

It is noted that a measurement system may be configured in such a way that the measurement system uses more than one technology. In fact, an application may be configured to employ any combination of available metrology sub-systems within a single tool, or across a number of different tools.

A system implementing the methods described herein may also be configured in a number of different ways. For example, a wide range of wavelengths (including visible, ultraviolet, and infrared), angles of incidence, states of polarization, and states of coherence may be contemplated. In another example, the system may include any of a number of different light sources (e.g., a directly coupled light source, a laser-sustained plasma light source, etc.). In another example, the system may include elements to condition light directed to or collected from the specimen (e.g., apodizers, filters, etc.).

In general, the optical dispersion properties of semiconductor structures under measurement may be approximated as isotropic. Under this assumption the material parameters are scalar values. Alternatively, the optical dispersion properties of semiconductor structures under measurement may be more accurately modelled as anisotropic. Under this assumption, the material parameters will be a matrix of different values, rather than a scalar value. Additional details regarding the treatment of anisotropic structures under measurement is described in U.S. Patent Publication No. 2018/0059019, the content of which is incorporated herein by reference in its entirety.

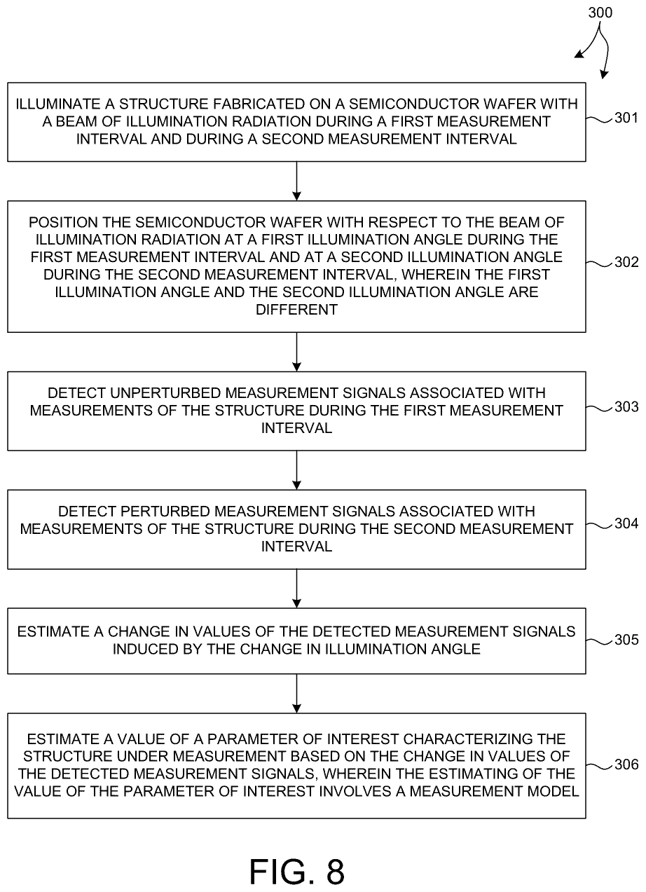

FIG. 8 illustrates a method 300 suitable for implementation by the metrology system 100 of the present invention. In one aspect, it is recognized that data processing blocks of method 300 may be carried out via a pre-programmed algorithm executed by one or more processors of computing system 130. While the following description is presented in the context of metrology system 100, it is recognized herein that the particular structural aspects of metrology system 100 do not represent limitations and should be interpreted as illustrative only.

In block 301, a structure fabricated on a semiconductor wafer is illuminated with a beam of illumination radiation during a first measurement interval and during a second measurement interval.

In block 302, the semiconductor wafer is positioned with respect to the beam of illumination radiation at a first illumination angle during the first measurement interval and at a second illumination angle during the second measurement interval. The first illumination angle and the second illumination angle are different.

In block 303, unperturbed measurement signals associated with measurements of the structure are detected during the first measurement interval.

In block 304, perturbed measurement signals associated with measurements of the structure are detected during the second measurement interval.

In block 305, a change in values of the detected measurement signals induced by the change in illumination angle is estimated.

In block 306, a value of a parameter of interest characterizing the structure under measurement is estimated based on the change in values of the detected measurement signals. The estimation of the value of the parameter of interest involves a measurement model.

It should be recognized that the various steps described throughout the present disclosure may be carried out by a single computer system, or, alternatively, multiple computer systems. Moreover, different subsystems, such as the spectroscopic ellipsometer 101, may include a computer system suitable for carrying out at least a portion of the steps described herein. Therefore, the aforementioned description should not be interpreted as a limitation on the present invention but merely an illustration. Further, the one or more computing systems 130 may be configured to perform any other step(s) of any of the method embodiments described herein.

The computing system 130 may include, but is not limited to, a personal computer system, mainframe computer system, workstation, image computer, parallel processor, or any other computing device known in the art. In general, the term “computing system” may be broadly defined to encompass any device having one or more processors, which execute instructions from a memory medium. In general, computing system 130 may be integrated with a measurement system such as measurement system 100, or alternatively, may be separate from any measurement system. In this sense, computing system 130 may be remotely located and receive measurement data and user input from any measurement source and user input source, respectively.

Program instructions 134 implementing methods such as those described herein may be transmitted over or stored on carrier medium. The carrier medium may be a transmission medium such as a wire, cable, or wireless transmission link. The carrier medium may also include a computer-readable medium such as a read-only memory, a random access memory, a magnetic or optical disk, or a magnetic tape. For example, as illustrated in FIG. 3, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

As described herein, the term “critical dimension” includes any critical dimension of a structure (e.g., bottom critical dimension, middle critical dimension, top critical dimension, sidewall angle, grating height, trench depth, etc.), a critical dimension between any two or more structures (e.g., distance between two structures), a displacement between two or more structures (e.g., overlay displacement between overlaying grating structures, etc.), and a dispersion property value of a material used in the structure or part of the structure. Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect. However, such terms of art do not limit the scope of the term “metrology system” as described herein. The metrology system may be configured as a LED inspection tool, edge inspection tool, backside inspection tool, macro-inspection tool, or multi-mode inspection tool (involving data from one or more platforms simultaneously), and any other metrology or inspection tool.

Various embodiments are described herein for a semiconductor processing system (e.g., an inspection system or a lithography system) that may be used for processing a specimen. The term “specimen” is used herein to refer to a site, or sites, on a wafer, a reticle, or any other sample that may be processed (e.g., printed, measured, or inspected for defects) by means known in the art. In some examples, the specimen includes a single site having one or more measurement targets whose simultaneous, combined measurement is treated as a single specimen measurement or reference measurement. In some other examples, the specimen is an aggregation of sites where the measurement data associated with the aggregated measurement site is a statistical aggregation of data associated with each of the multiple sites. Moreover, each of these multiple sites may include one or more measurement targets associated with a specimen or reference measurement.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A metrology system comprising:
an illumination subsystem configured to illuminate a structure fabricated on a semiconductor wafer with a beam of illumination radiation during a first measurement interval and during a second measurement interval;
a specimen positioning system configured position the semiconductor wafer with respect to the beam of illumination radiation at a first illumination angle during the first measurement interval and at a second illumination angle during the second measurement interval, wherein the first illumination angle and the second illumination angle are different;
a detector configured to detect unperturbed measurement signals associated with measurements of the structure during the first measurement interval and detect perturbed measurement signals associated with measurements of the structure during the second measurement interval; and
a computing system configured to:
estimate a change in values of the detected measurement signals induced by the change in illumination angle; and
estimate a value of a parameter of interest characterizing the structure under measurement based on the change in values of the detected measurement signals, wherein the estimating of the value of the parameter of interest involves a measurement model.

2. The metrology system of claim 1, wherein a difference between the first illumination angle and the second illumination angle is characterized by a different angle of incidence, a different azimuth angle, or both.

3. The metrology system of claim 1, wherein the estimating of the change in values of the detected measurement signals induced by the change in illumination angle involves determining at least one derivative of the detected measurement signals with respect to the illumination angle.

4. The metrology system of claim 3, wherein the at least one determined derivative of the detected measurement signals with respect to the illumination angle is a first order derivative, one or more higher order derivatives, or both.

5. The metrology system of claim 1, the computing system further configured to:
estimate a value of a model parameter of the measurement model based on the change in values of the detected measurement signals.

6. The metrology system of claim 1, wherein the detected measurement signals are associated with measurements of the structure at multiple wavelengths.

7. The metrology system of claim 2, wherein the parameter of interest is any of a critical dimension, a film thickness, or a material property.

8. The metrology system of claim 1, wherein the metrology system is an optically based metrology system, an electron based metrology system, or an x-ray based metrology system.

9. The metrology system of claim 1, the specimen positioning system, comprising:
a two axis wafer stage configured to locate the semiconductor wafer with respect to the illumination source and the detector at any location on the surface of the semiconductor wafer;
a wafer chuck configured to removably couple the semiconductor wafer to the specimen positioning system;
a rotational actuator mechanically coupled to the wafer chuck, the rotational actuator configured to rotate the wafer chuck about an axis perpendicular to the surface of the semiconductor wafer coupled to the wafer chuck; and
at least three actuators spaced apart from one another, wherein each of the at least three actuators is mechanically coupled between the wafer chuck and the two axis wafer stage, wherein a direction of extent of each of the at least three actuators is approximately parallel to a direction normal to the surface of the semiconductor wafer when coupled to the wafer chuck.

10. The metrology system of claim 9, the specimen positioning system further comprising:
at least three position sensors, each of the at least three position sensors located in close proximity to a corresponding actuator of the at least three actuators, wherein each of the at least three position sensors measures a displacement in the direction of extent of each corresponding actuator; and
a rotational position sensor located in close proximity to the rotary actuator, wherein the rotational position sensor measures a rotational position of the semiconductor wafer with respect to the beam of illumination radiation about the axis perpendicular to the surface of the semiconductor wafer.

11. The metrology system of claim 1, wherein the detected measurement signals are values of one or more Mueller matrix elements, values of one or more harmonic signals, or values of one or more detected image signals.

12. The metrology system of claim 1, wherein the structure under measurement is an array of partially fabricated transistor devices.

13. A method comprising:
illuminating a structure fabricated on a semiconductor wafer with a beam of illumination radiation during a first measurement interval and during a second measurement interval;
positioning the semiconductor wafer with respect to the beam of illumination radiation at a first illumination angle during the first measurement interval and at a second illumination angle during the second measurement interval, wherein the first illumination angle and the second illumination angle are different;
detecting unperturbed measurement signals associated with measurements of the structure during the first measurement interval;
detecting perturbed measurement signals associated with measurements of the structure during the second measurement interval;
estimating a change in values of the detected measurement signals induced by the change in illumination angle; and
estimating a value of a parameter of interest characterizing the structure under measurement based on the change in values of the detected measurement signals, wherein the estimating of the value of the parameter of interest involves a measurement model.

14. The method of claim 13, wherein a difference between the first illumination angle and the second illumination angle is characterized by a different angle of incidence, a different azimuth angle, or both.

15. The method of claim 13, wherein the estimating of the change in values of the detected measurement signals induced by the change in illumination angle involves determining at least one derivative of the detected measurement signals with respect to the illumination angle.

16. The method of claim 15, wherein the at least one determined derivative of the detected measurement signals with respect to the illumination angle is a first order derivative, one or more higher order derivatives, or both.

17. The method of claim 13, further comprising:
estimating a value of a model parameter of the measurement model based on the change in values of the detected measurement signals.

18. The method of claim 13, wherein the detected measurement signals are associated with measurements of the structure at multiple wavelengths.

19. The method of claim 13, wherein the detected measurement signals are values of one or more Mueller matrix elements, values of one or more harmonic signals, or values of one or more detected image signals.

20. A metrology system comprising:
an illumination subsystem configured to illuminate a structure fabricated on a semiconductor wafer with a beam of illumination radiation during a first measurement interval and during a second measurement interval;
a specimen positioning system configured position the semiconductor wafer with respect to the beam of illumination radiation at a first illumination angle during the first measurement interval and at a second illumination angle during the second measurement interval, wherein the first illumination angle and the second illumination angle are different;
a detector configured to detect unperturbed measurement signals associated with measurements of the structure during the first measurement interval and detect perturbed measurement signals associated with measurements of the structure during the second measurement interval; and
a non-transitory, computer-readable medium storing instructions that, when executed by one or more processors, causes the one or more processors to:
estimate a change in values of the detected measurement signals induced by the change in illumination angle; and
estimate a value of a parameter of interest characterizing the structure under measurement based on the change in values of the detected measurement signals, wherein the estimating of the value of the parameter of interest involves a measurement model.
